(19) United States
(12) Patent Application Publication
(10) Pub. No.: US 2015/0062854 A1
(43) Pub. Date: Mar. 5, 2015

(54) ELECTRONIC COMPONENT MODULE AND METHOD OF MANUFACTURING THE SAME

(71) Applicant: SAMSUNG ELECTRO-MECHANICS CO., LTD., Suwon-Si (KR)

(72) Inventors: Seung Yong CHOI, Suwon-Si (KR); II Hyeong LEE, Suwon-Si (KR); Jae Cheon DOH, Suwon-Si (KR)

(73) Assignee: SAMSUNG ELECTRO-MECHANICS CO., LTD., Suwon-Si (KR)

(21) Appl. No.: 14/273,432

(22) Filed: May 8, 2014

(30) Foreign Application Priority Data
Aug. 28, 2013 (KR) 10-2013-0102356

(51) Int. Cl. H05K 1/14; H05K 3/30; H05K 1/18

(52) U.S. Cl. CPC H05K 1/144; H05K 1/181; H05K 3/30; H05K 2201/10545
USPC 361/784; 29/832

(57) ABSTRACT

There are provided an electronic component module in which electronic components are mounted on both surfaces of a substrate to increase integration density, and a method of manufacturing the same, the electronic component module including a first substrate; a plurality of electronic components mounted on both surfaces of the first substrate; a second substrate bonded to a lower surface of the first substrate; and a molded part formed on the lower surface of the first substrate and having the second substrate embedded therein.

### CROSS-REFERENCE TO RELATED APPLICATION

This application claims the benefit of Korean Patent Application No. 10-2013-0102356 filed on Aug. 28, 2013, with the Korean Intellectual Property Office, the disclosure of which is incorporated herein by reference.

### BACKGROUND

The present disclosure relates to an electronic component module and a method of manufacturing the same, and more particularly, to an electronic component module in which electronic components are mounted on both surfaces of a substrate to increase integration density, and a method of manufacturing the same.

Recently, market demand for portable electronic devices has increased in the area of electronic products. Accordingly, the miniaturization and lightening of electronic components mounted in electronic devices is in continual demand.

In order to realize the miniaturization and lightening of electronic devices, a system on chip (SOC) technology of implementing a plurality of individual elements on a single chip, a system in package (SIP) technology in which a plurality of individual elements are integrated in a single package, or the like, as well as a technology of reducing individual sizes of mounting components may be required.

Meanwhile, in order to manufacture an electronic component module having a small size and high performance, a structure in which electronic components are mounted on both surfaces of a substrate has also been developed.

However, in the case of such an electronic component module in which electronic components are mounted on both surfaces of a substrate, it may be difficult to form an external connection terminal on the substrate.

That is, since electronic components are mounted on both surfaces of a substrate, space for forming an external connection terminal may not be accurately secured. Accordingly, a double-sided mounting type electronic component module allowing for the easy formation of an external connection terminal and a method of easily manufacturing the double-sided mounting type electronic component module are in demand.

### RELATED ART DOCUMENT

(Patent Document 1) Korean Patent Laid-Open Publication No. 2013-0056570

### SUMMARY

An aspect of the present disclosure may provide a double-sided mounting type electronic component module allowing for electronic components to be mounted on both surfaces of a substrate.

An aspect of the present disclosure may also provide a method of easily manufacturing a double-sided mounting type electronic component module.

According to an aspect of the present disclosure, an electronic component module may include a first substrate; a plurality of electronic components mounted on both surfaces of the first substrate; a second substrate bonded to a lower surface of the first substrate; and a molded part formed on the lower surface of the first substrate and having the second substrate embedded therein.

The electronic component module may further include a plurality of external connection terminals bonded to a lower surface of the second substrate and penetrating through the molded part to be exposed to the outside of the molded part.

The molded part may fill a gap formed between the lower surface of the first substrate and an upper surface of the second substrate.

The molded part may be formed on the lower surface of the first substrate, while embedding the electronic components mounted on a lower portion of the first substrate and the entirety of the second substrate therein.

The second substrate may include a through portion formed therein and may be bonded to the lower surface of the first substrate to accommodate the electronic components mounted on the lower surface of the first substrate in the through portion.

The second substrate may include a plurality of substrates spaced apart from each other and dispersedly disposed.

The second substrate may be formed to be smaller than the first substrate and may be disposed on a central portion of the first substrate, and the electronic components may be disposed outside of the second substrate.

The second substrate may include a substrate frame; and a plurality of metallic pins penetrating through and coupled to the substrate frame and having one ends bonded to the first substrate.

The other ends of the metallic pins may be exposed to the outside of the molded part.

The electronic component module may further include a plurality of external connection terminals bonded to the other ends of the metallic pins.

According to another aspect of the present disclosure, an electronic component module may include a first substrate; a plurality of electronic components mounted on both surfaces of the first substrate; a second substrate bonded to a lower surface of the first substrate; and a molded part formed on the both surfaces of the first substrate to encapsulate the electronic components and the second substrate.

The electronic component module may further include a plurality of external connection terminals bonded to a lower surface of the second substrate and penetrating through the molded part to be exposed to the outside of the molded part.

According to another aspect of the present disclosure, a method of manufacturing an electronic component module may include preparing a first substrate; mounting electronic components on an upper surface of the first substrate; forming a first molded part on the upper surface of the first substrate; mounting a plurality of second substrates and electronic components on a lower surface of the first substrate; and forming a second molded part to embed the second substrates therein.

The mounting of the plurality of second substrates may include applying a solder paste onto the lower surface of the first substrate; disposing the electronic components and the plurality of second substrates on the solder paste; and hardening the solder paste to fixedly bond the electronic components and the second substrates to the lower surface of the first substrate.

The method may further include forming external connection terminals on the second substrates after the forming of the second molded part.

The forming of the external connection terminals may include forming terminal holes in a lower surface of the second molded part; and forming the external connection terminals on the second substrates through the terminal holes.

The forming of the terminal holes may include forming the through holes in positions corresponding to electrode pads formed on the second substrates.

Each of the second substrates may include a through portion formed therein and may be bonded to the lower surface of the first substrate to accommodate the electronic components mounted on the lower surface of the first substrate in the through portion.

Each of the second substrates may include a plurality of substrates spaced apart from each other and dispersedly disposed.

The second substrates may be formed to be smaller than the first substrate and may be disposed on a central portion of the first substrate, and the electronic components may be disposed outside of the second substrates.

The second substrate may include a substrate frame; and a plurality of metallic pins penetrating through and coupled to the substrate frame and having one ends bonded to the first substrate.

The method may further include: after the forming of the second molded part, grinding a lower surface of the second molded part to expose the other ends of the metallic pins; and forming external connection terminals on the other ends of the metallic pins.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic cross-sectional view of an electronic component module according to an exemplary embodiment of the present disclosure;

FIG. 2 is a partially cut-away perspective view illustrating an interior of the electronic component module illustrated in FIG. 1;

FIG. 3 is an exploded perspective view of the electronic component module illustrated in FIG. 1;

FIGS. 4A to 41 are cross-sectional views illustrating a method of manufacturing an electronic component module according to an exemplary embodiment of the present disclosure;

FIG. 5 is a schematic cross-sectional view of an electronic component module according to another exemplary embodiment of the present disclosure;

FIG. 6 is a schematic cross-sectional view of an electronic component module according to another exemplary embodiment of the present disclosure; and

FIG. 7 is a schematic cross-sectional view of an electronic component module according to another exemplary embodiment of the present disclosure.

### DETAILED DESCRIPTION

Hereinafter, exemplary embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

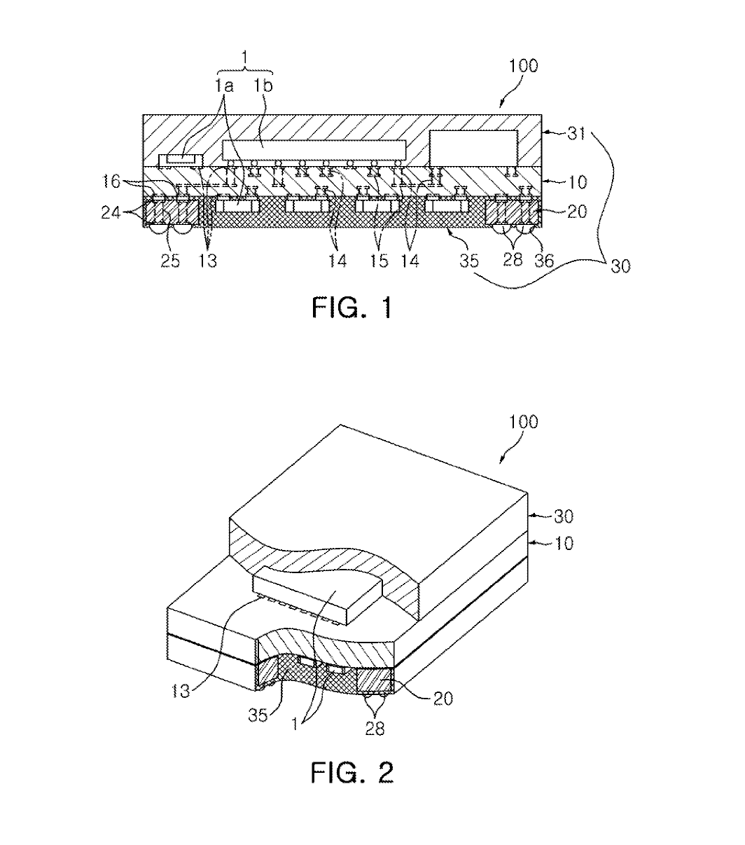

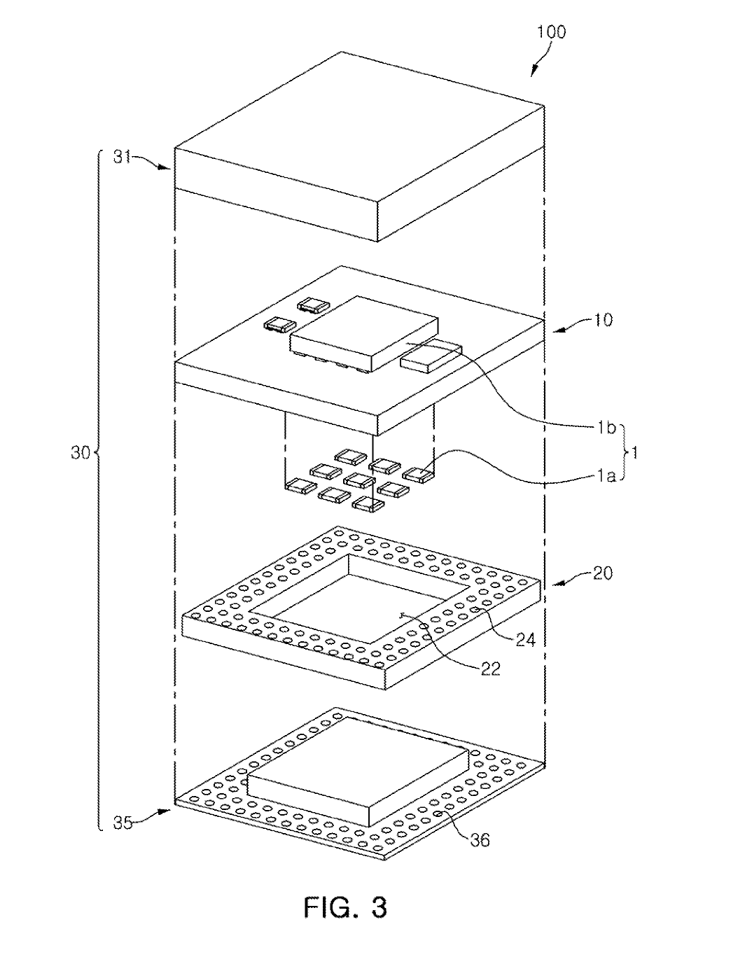

FIG. 1 is a schematic cross-sectional view of an electronic component module 100 according to an exemplary embodiment of the present disclosure. FIG. 2 is a partially cut-away perspective view illustrating an interior of the electronic component module 100 illustrated in FIG. 1. FIG. 3 is an exploded perspective view of the electronic component module 100 illustrated in FIG. 1.

Referring to FIGS. 1 to 3, the electronic component module 100 according to the exemplary embodiment may include electronic components 1, a first substrate 10, a second substrate 20, and molded parts 30.

The electronic components 1 may include various components such as passive components 1a and an active component 1b, and all types of components may be used as the electronic components 1, as long as they may be mounted on the substrate.

The electronic components 1 may be mounted on both upper and lower surfaces of the first substrate 10 to be described below. FIG. 1 illustrates an example in which both of the active component 1b and the passive component 1a are mounted on the upper surface of the first substrate 10 and only the passive components 1a are mounted on the lower surface of the first substrate 10. However, exemplary embodiments of the present disclosure are not limited thereto. Alternatively, the electronic components 1 may be arranged on both surfaces of the first substrate 10 in various manners according to sizes or shapes of the electronic components 1, and the design of the electronic component module 100.

At least one electronic component 1 may be mounted on each of the upper and lower surfaces of the first substrate 10. As the first substrate 10, various kinds of substrates well known in the art, (a ceramic substrate, a printed circuit board, a flexible substrate, and the like for example), may be used. In addition, mounting electrodes 13 for mounting the electronic components 1 may be formed on the both surfaces of the first substrate 10, or although not illustrated, wiring patterns for electrically connecting the mounting electrodes 13 to each other may be formed on the both surfaces of the first substrate 10.

The first substrate 10 according to the exemplary embodiment may be a multilayer substrate including a plurality of layers, and circuit patterns 15 for forming electrical connections may be formed between the respective layers.

In addition, the first substrate 10 according to the exemplary embodiment of the present disclosure may include conductive vias 14 for forming electrical connections between the mounting electrodes 13 formed on the both surfaces of the first substrate 10 and the circuit patterns 15 formed in the first substrate 10.

In addition, the first substrate 10 according to the exemplary embodiment may include cavities (not shown) formed therein to accommodate the electronic components 1.

The first substrate 10 according to the exemplary embodiment may include external connection pads 16 formed on the lower surface thereof. The external connection pads 16 may be electrically connected to the second substrate 20 to be described below and may be connected to external connection terminals 28 through the second substrate 20.

Thus, the external connection pads 16 may be formed on positions of the lower surface of the first substrate 10, facing an upper surface of the second substrate 20 when the second substrate 20 is coupled to the first substrate 10. As necessary, a plurality of external connection pads may be arranged in various manners.

The second substrate 20 is disposed on a lower portion of the first substrate 10 and is coupled to the first substrate 10.

The second substrate 20 may be formed of a single substrate or a plurality of substrates. According to the exemplary embodiment, the second substrate 20 may be configured of a single substrate and have a through portion 22 formed therein, the through portion 22 having a through hole shape.

The through portion 22 may be used as a space for accommodating the electronic components 1 mounted on the lower surface of the first substrate 10. Thus, the electronic components 1 mounted on the lower surface of the first substrate 10 may be mounted only on a portion of the lower surface of the first substrate 10, facing the through portion 22 of the second substrate 20.

However, the configuration of the present disclosure is not limited thereto.

Similarly to the case of the first substrate 10, various types of substrates, such as a ceramic substrate, a printed circuit board (PCB), a flexible substrate, or the like, well known in the art to which the present disclosure pertains may be used as the second substrate 20.

The second substrate 20 may be formed by preparing a plurality of insulating layers including vias formed therein and then stacking the insulating layers to electrically connect the vias to each other, or alternatively, may be formed by stacking a plurality of insulating layers, forming a through hole penetrating through the insulating layers, and then, forming a via in the through hole. In addition, the second substrate 20 may be formed in various manners, and for example, may be formed by preparing one resin layer (e.g., an epoxy layer or the like) and forming a plurality of metallic posts (e.g., a copper (Cu) post) through the resin layer to be embedded therein.

Electrode pads 24 may be formed on both surfaces of the second substrate 20. The electrode pads 24 formed on the upper surface of the second substrate 20 may be used to be electrically connected to the external connection pads 16 of the first substrate 10. In addition, the electrode pads 24 formed on the lower surface of the second substrate 20 may be used for coupling with the external connection terminals 28. Although not illustrated, wiring patterns for electrically connecting the electrode pads 24 to each other may be formed on the both surfaces of the second substrate 20.

The second substrate 20 according to the exemplary embodiment may be a multilayer substrate including a plurality of layers, and circuit patterns (not shown) for forming electrical connections may be formed between the respective layers.

The second substrate 20 may include the electrode pads 24 formed on the both surfaces thereof and conductive vias 25 electrically connecting the circuit patterns formed in the second substrate 20.

In addition, the second substrate 20 according to the exemplary embodiment may have a thickness greater than a mounting thickness of the electronic components 1 mounted on the lower surface of the first substrate 10 in order to stably protect the electronic components 1 mounted in the through portion 22. However, exemplary embodiments of the present disclosure are not limited thereto.

The external connection terminals 28 may be formed on the lower surface of the second substrate 20. The external connection terminals 28 may be used to electrically and physically connect the electronic component module 100 to a main substrate (not shown) on which the electronic component module 100 is mounted.

The external connection terminals 28 may be formed on the electrode pads 24 formed on the lower surface of the second substrate 20. The external connection terminals 28 may be formed in the form of bumps. However, embodiments of the present disclosure are not limited thereto. For example, the external connection terminals 28 may be formed in various manners such as in the form of solder balls, or the like.

The external connection terminals 28 are electrically connected to the electrode pads 24 formed on the upper surface of the second substrate 20 through the conductive vias 25. Thus, when the second substrate 20 is coupled to the first substrate 10, the first substrate 10 may be electrically connected to the external connection terminals 28 through the second substrate 20.

In addition, the external connection terminals 28 may be mounted on the second substrate 20 through terminal holes 36 of a second molded part 35 that will be described later. Thus, a height (vertical length) of the external connection terminals 28 may be formed to be greater than a thickness of the second molded part 35 formed on a lower portion of the second substrate 20.

The second substrate 20 according to the exemplary embodiment may be formed to be smaller than the first substrate 10. That is, a width of the second substrate 20 may be smaller than that of the first substrate 10. Such a structure may be conceived to easily manufacture the electronic component module 100, which will be described in more detail with regard to a manufacturing method to be described below.

The molded parts 30 may include a first molded part 31 formed on the upper surface of the first substrate 10 and the second molded part 35 formed on the lower surface of the first substrate 10.

The first molded part 31 may encapsulate the electronic components 1 mounted on the upper surface of the first substrate 10.

The first molded part 31 may be disposed between the electronic components 1 mounted on the first substrate 10, thereby preventing electrical short circuits between the electronic components 1. In addition, the molded parts 30 may enclose external portions of the electronic components 1 and fix the electronic components 1 onto the substrate, thereby securely protecting the electronic components 1 from external impacts.

The first molded part 31 may be formed of an insulating material including a resin material such as epoxy, or the like. In addition, the first molded part 31 according to the exemplary embodiment may be formed by accommodating the first substrate 10 including the electronic components 1 mounted thereon in a mold (not shown) and subsequently, injecting molding resin into the mold. However, embodiments of the present disclosure are not limited thereto.

The second molded part 35 may be formed in an inner portion of the through portion 22 of the second substrate 20 and outside of the second substrate 20. Here, the second molded part 35 may be formed to cover the entirety of the second substrate 20 such that the second substrate 20 is embedded therein. However, embodiments of the present disclosure are not limited thereto. That is, the second substrate 20 may be formed to be partially exposed to the outside.

The second molded part 35 according to the exemplary embodiment may be disposed to fill the entirety of the inner portion of the through portion 22. Thus, all of the electronic components 1 accommodated in the through portion 22 may be embedded in the second molded part 35. However, as necessary, a portion of the electronic components 1 may be exposed outside of the second molded part 35.

The second molded part 35 according to the exemplary embodiment may include the terminal holes 36. The terminal holes 36 may be holes for mounting the external connection terminals 28 on the lower surface of the second substrate 20. Accordingly, a plurality of the terminal holes 36 may be formed to correspond to the electrode pads 24 formed on the lower surface of the second substrate 20 and may have a predetermined size in order to enable the external connection terminals 28 to be easily mounted on the electrode pads 24 of the second substrate 20.

The second molded part 35 may be formed by a molding method for injecting molding resin, in a similar manner to that of the first molded part 31. That is, the second molded part 35 may be formed by disposing the first substrate 10 having the lower surface thereof on which the electronic components 1 and the second substrate 20 are mounted, in a mold (not shown) and subsequently, injecting molding resin into the mold. However, embodiments of the present disclosure are not limited thereto.

In the electronic component module 100 according to the exemplary embodiment configured as described above, the electronic components 1 may be mounted on the both surfaces of the first substrate 10. In addition, the external connection terminals 28 are formed on the second substrate 20 disposed on the lower surface of the first substrate 10.

Thus, a plurality of the electronic components 1 may be mounted on a single substrate (that is, the first substrate 10), thereby increasing integration density. In addition, the external connection terminals 28 for the first substrate 10 on which the electronic components 1 are mounted may be formed using the second substrate 20 provided as a separate substrate, and thus, the formation of the external connection terminals 28 may be facilitated.

Even in a case in which the electronic components 1 are mounted on the both surfaces of the first substrate 10, the electronic component module 100 according to the exemplary embodiment may be entirely encapsulated by the first and second molded parts 30. Thus, even in a case in which the second substrate 20 or the electronic components 1 are separated from the first substrate 10 due to heat generated at the time of mounting the electronic component module 100 on another main substrate, movements of the electronic component module 100 may be fixed by the molded parts 30.

Thus, bonding reliability between the electronic components and the substrate may be enhanced.

Hereinafter, a method of manufacturing an electronic component module according to an exemplary embodiment will be described below.

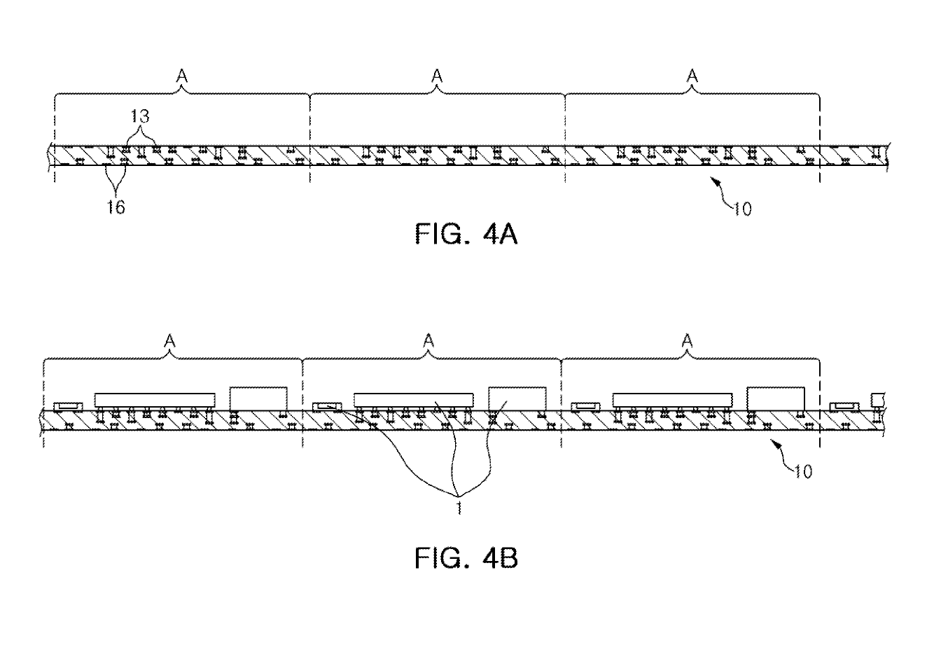

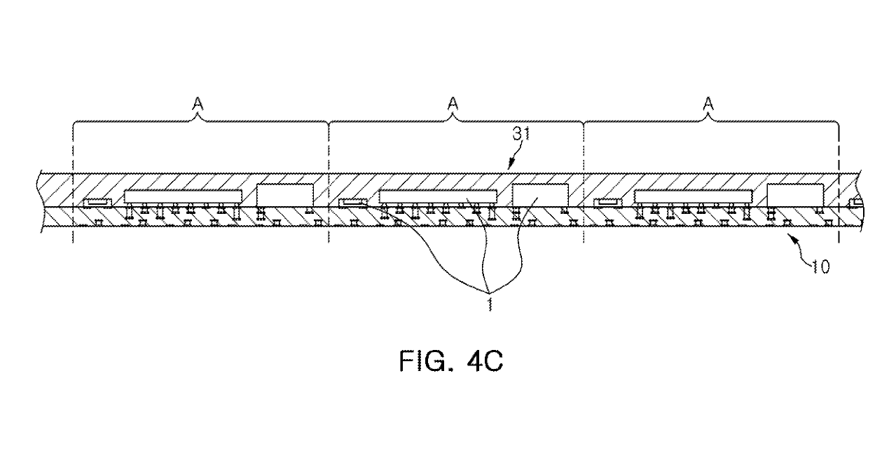

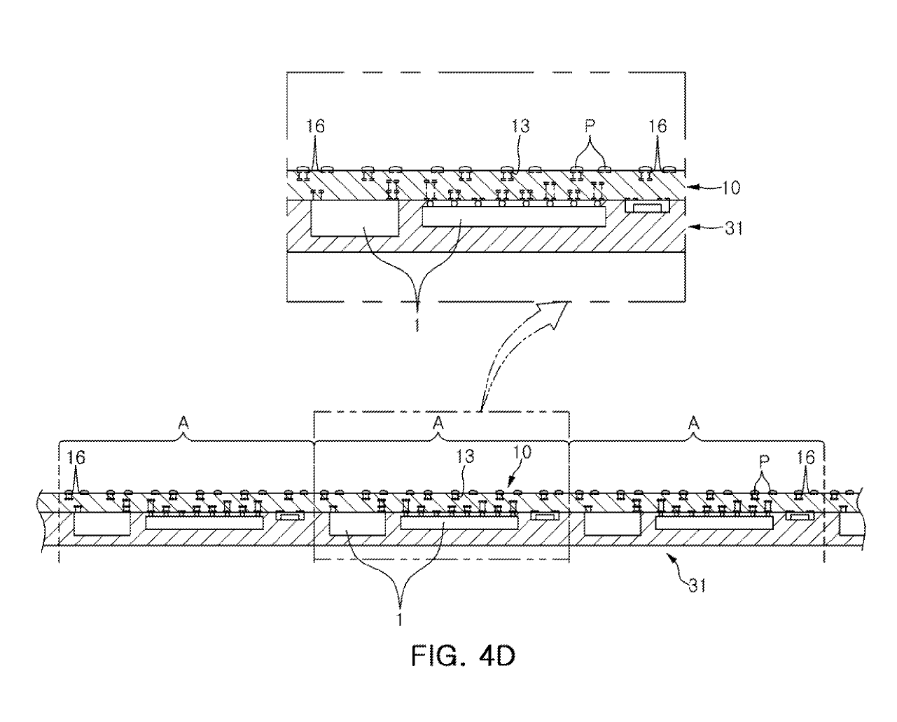

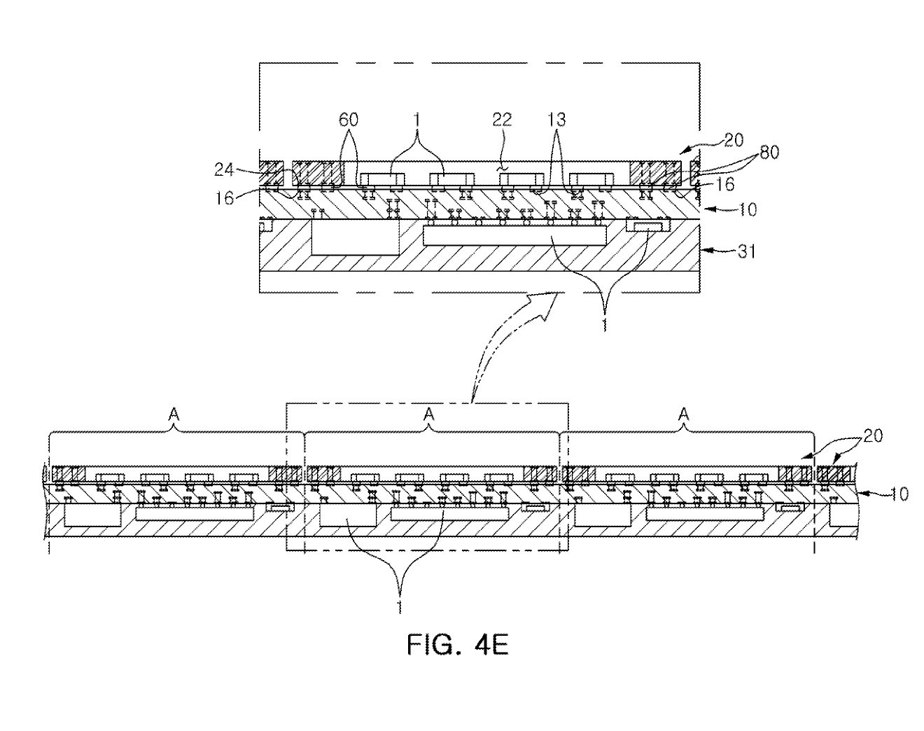

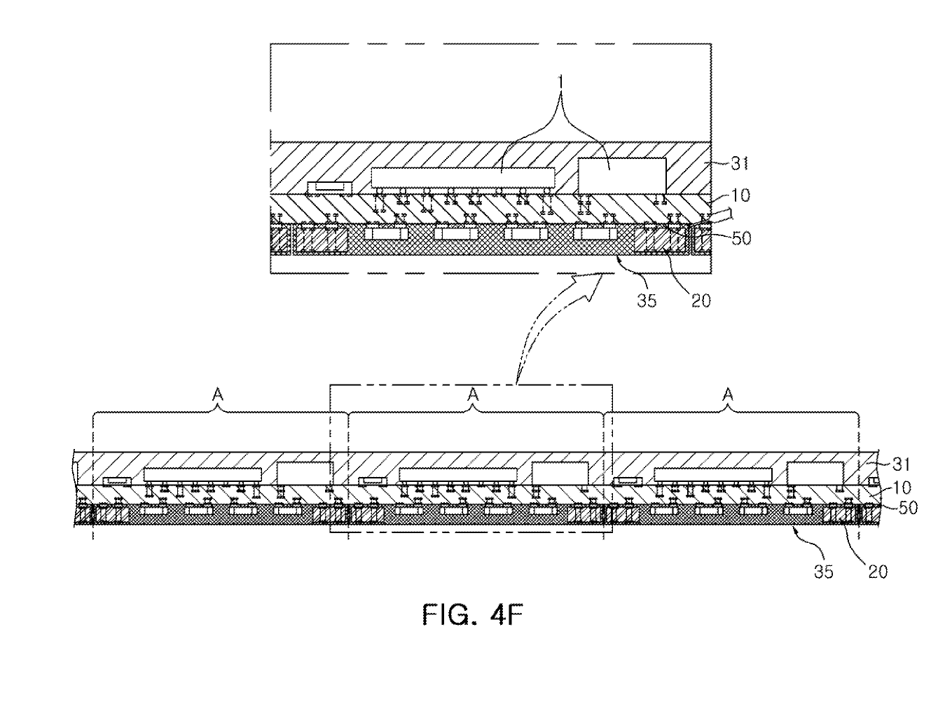

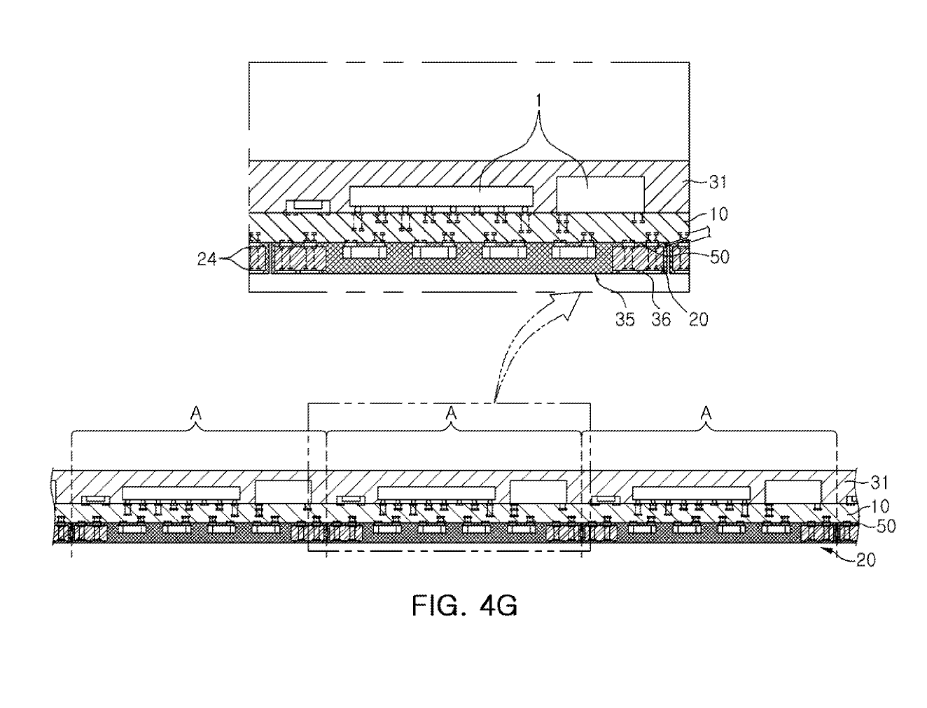

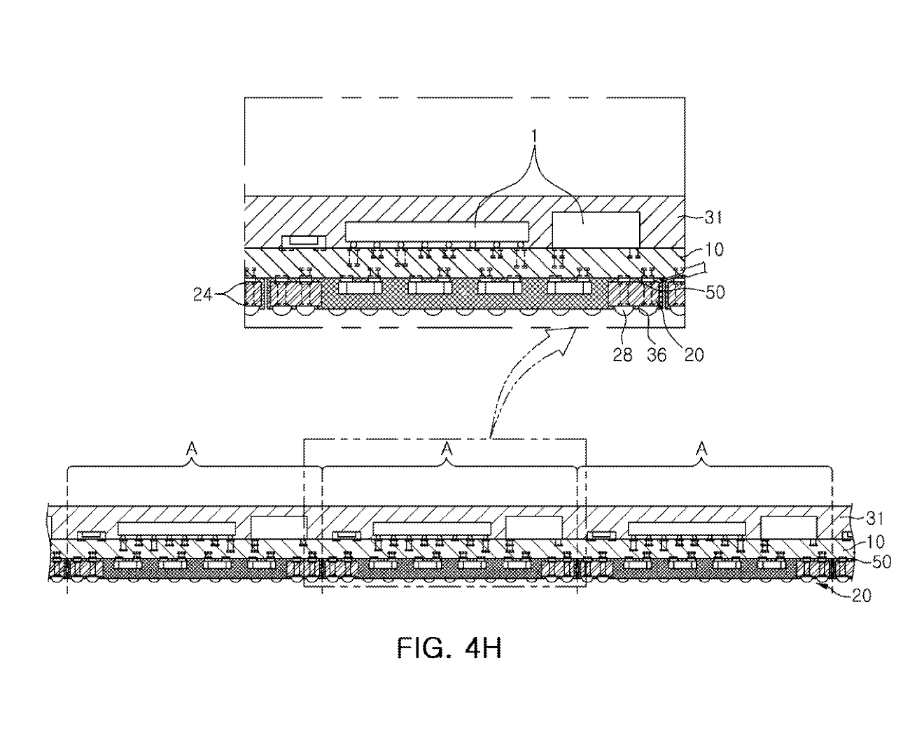

FIGS. 4A to 41 are cross-sectional views illustrating a method of manufacturing an electronic component module according to an exemplary embodiment of the present disclosure.

First, as illustrated in FIG. 4A, the first substrate 10 is prepared. As described above, the first substrate 10 may be a multilayer substrate. The mounting electrodes 13 may be formed on both surfaces of the first substrate 10. In addition, the external connection pads 16 may be formed on the lower surface of the first substrate 10.

In particular, the first substrate 10 prepared in the process may be a substrate on which a plurality of identical mounting regions A are repeatedly arranged. The first substrate 10 may be a quadrangular substrate having a wide area or an elongated strip shaped substrate.

The first substrate 10 may be formed to simultaneously manufacture a plurality of individual modules. In this regard, the plurality of individual module mounting regions A are separately formed on the first substrate 10, and electronic component modules may be manufactured in the plurality of individual module mounting regions A.

Then, as illustrated in FIG. 4B, the electronic components 1 are mounted on one surface, that is, the upper surface of the first substrate 10. The operation of mounting the electronic components 1 may be performed by printing a solder paste on the mounting electrodes 13 formed on one surface of the first substrate 10 using a screen printing method, or the like, disposing the electronic components 1 on the printed solder paste, and then, applying heat to the solder paste to harden the solder paste.

In this case, the identical electronic components 1 may be mounted on the respective module mounting regions A in the same arrangement manner.

Then, as illustrated in FIG. 4C, the first molded part 31 may be formed on one surface of the first substrate 10 to encapsulate the electronic components 1. In the present operation, as described above, the first molded part 31 may be formed by disposing the first substrate 10 including the electronic components 1 mounted thereon in a mold (not shown) and then injecting molding resin into the mold. As the first molded part 31 is formed, the electronic components 1 mounted on one surface, that is, the upper surface of the first substrate 10 may be protected from the outside by the first molded part 31.

The first molded part 31 according to the exemplary embodiment may be formed in an integrated type to cover all the plurality of individual module mounting regions A on the first substrate 10. However, embodiments of the present disclosure are not limited thereto. As necessary, the first molded part 31 may be divided and formed independently on each of the individual module mounting regions A.

Then, as illustrated in FIG. 4D, a solder paste P is printed on the other surface, that is, the lower surface of the first substrate 10 on which the first molded part 31 is formed. In this case, the solder paste P is printed on the external connection pads 16 as well as on the mounting electrodes 13.

Then, as illustrated in FIG. 4E, the electronic components 1 and the second substrate 20 are mounted on the other surface of the first substrate 10 on which the solder paste P is printed.

The mounting operation may be performed by disposing the electronic components 1 on the mounting electrodes 13 and disposing the second substrate 20 on the external connection pads 16. The disposition operation may be performed by disposing the electronic components 1 and subsequently, disposing the second substrate 20. However, embodiments of the present disclosure are not limited thereto. That is, the second substrate 20 may be disposed first. Alternatively, the second substrate 20 and the electronic components 1 may be simultaneously disposed, for example. The disposition operation may be performed in various manners.

The second substrate 20 according to the exemplary embodiment may be configured of a plurality of substrates that are separately attached to the respective separate module mounting regions A, rather than a single substrate having the plurality of individual module mounting regions A in a similar manner to the first substrate 10.

That is, the second substrate 20 may include a plurality of substrates having the same shape as one another, and the plurality of substrates may be repeatedly arranged in the respective separate module mounting regions A of the first substrate 10. In this case, the substrates adjacent to each other in the second substrate 20 may be mounted on the first substrate 10 to be spaced apart from each other at a predetermined interval S.

When the electronic components 1 and the second substrate 20 are disposed on the other surface of the first substrate 10, heat is applied to harden the solder paste P (refer to FIG. 4D). Through this process, the solder paste P is melted and hardened to form a solder connection portion 80, and the electronic components 1 and the plurality of substrates of the second substrate 20 disposed on the lower surface of the first substrate 10 may be stably fixed to the first substrate 10 by the solder connection portion 80 to thereby be electrically and physically connected to the first substrate 10.

Then, as illustrated in FIG. 4F, the second molded part 35 is formed on the lower surface of the first substrate 10. In the operation, in a similar manner to the case of the first molded part 31, the second molded part 35 may be formed by disposing the first substrate 10 on which the electronic components 1 and the second substrate 20 are mounted in a mold and subsequently injecting molding resin into the mold.

Due to the presence of the second molded part 35, the electronic components 1 and the second substrate 20 mounted on the lower surface of the first substrate 10 may be embedded in the second molded part 35.

In the operation, the molding resin injected into the mold may also fill a gap formed between the first substrate 10 and the second substrate 20. That is, the second molded part 35 may be formed in the gap between the first substrate 10 and the second substrate 20.

In this case, the first substrate 10 and the second substrate 20 may have insulation therebetween by the second molded part 35 disposed therebetween and may also obtain coupling force between the first substrate 10 and the second substrate 20.

In addition, the second molded part 35 according to the exemplary embodiment may be separately and independently formed in the respective separate module mounting regions A. However, embodiments of the present disclosure are not limited thereto. That is, similar to the first molded part 31, the second molded part 35 may be formed in an integrated manner to cover all of the plurality of individual module mounting regions A.

Then, as illustrated in FIG. 4G, the terminal holes 36 are formed in the second molded part 35. As described above, the terminal holes 36 are provided to form the external connection terminals 28 on the second substrate 20. Thus, the terminal holes 36 may be formed to correspond to the electrode pads 24 of the second substrate 20.

The terminal holes 36 may be formed by laser drilling, but are not limited thereto.

Then, as illustrated in FIG. 4H, the external connection terminals 28 are formed on the lower surface of the second substrate 20. The external connection terminals 28 may be formed on the electrode pads 24 formed on the lower surface of the second substrate 20 in the form of bumps. However, embodiments of the present disclosure are not limited thereto. That is, the external connection terminals 28 may be formed in various manners such as in the form of solder balls, or the like.

In addition, the external connection terminals 28 may be formed on the second substrate 20 through the terminal holes 36 of the second molded part 35. Thus, the external connection terminals 28 may be disposed in the terminal holes 36 of the second molded part 35 and may partially protrude outside of the second molded part 35.

Finally, as illustrated in FIG. 4I, the first substrate 10 on which the molded parts 30 are formed may be cut to form individual electronic component modules 100.

In the operation, the first substrate 10 on which the molded parts 30 are formed may be cut using a blade 70 along a boundary between the individual module mounting regions A (refer to FIG. 4H).

In the electronic component module 100 according to the exemplary embodiment, the boundary between the individual module mounting regions A may correspond to a space between second molded parts 35 spaced apart from each other. Thus, cutting along the boundary between the individual module mounting regions A have the same meaning as cutting along the space between the spaced second molded parts 35.

Accordingly, in the method of manufacturing an electronic component module according to an exemplary embodiment of the present disclosure, since the cutting operation may be performed along the space between the second molded parts 35 using the blade 70, only the first molded part 31 and the first substrate 10 may be simply cut to separate electronic component modules 100 from each other.

Thus, compared with a case in which the second substrate 20 and the second molded part 35 are simultaneously cut, a cutting process may be facilitated and time for the cutting operation may be significantly reduced.

In the electronic component module 100 manufactured through the above described operations according to the exemplary embodiment, the second substrate 20 and the electronic components 1 (in particular, the electronic components mounted on the lower surface of the first substrate 10) may be simultaneously mounted, rather than coupling the first substrate 10 and the second substrate 20 to each other and subsequently, mounting the electronic components 1 on the substrate. That is, the electronic components 1 and the second substrate 20 are simultaneously mounted on the lower surface of the first substrate 10, and then, are hardened to be fixedly coupled to each other.

Accordingly, compared with a method in which the electronic components 1 and the second substrate 20 are separately bonded to the first substrate 10, the number of manufacturing processes may be reduced to allow for ease of manufacturing.

In addition, in the manufacturing method according to the exemplary embodiment, as the first substrate 10, a single substrate on which the plurality of individual module mounting regions A are divided may be used. As the second substrate 20, a plurality of substrates respectively disposed on the plurality of individual module mounting regions may be used.

Thus, in the cutting process, only the first molded part 31 and the first substrate 10 may be cut to separate the individual electronic component modules 100. Thus, the electronic component modules 100 may be easily manufactured and time required for manufacturing the same may be significantly reduced.

An electronic component module according to the present disclosure is not limited to the foregoing embodiments and various applications thereof may be enabled.

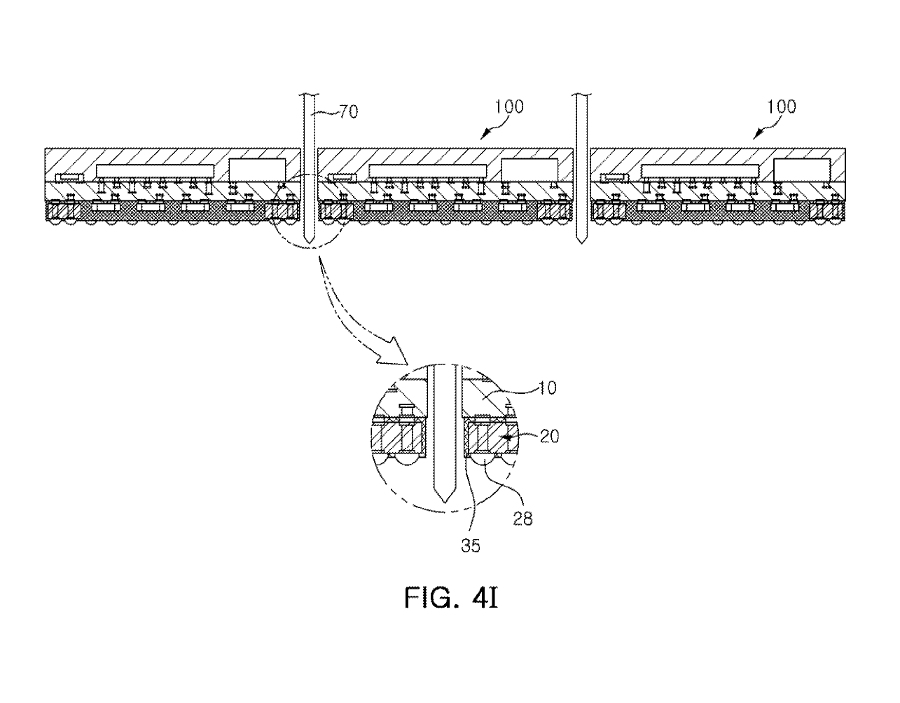

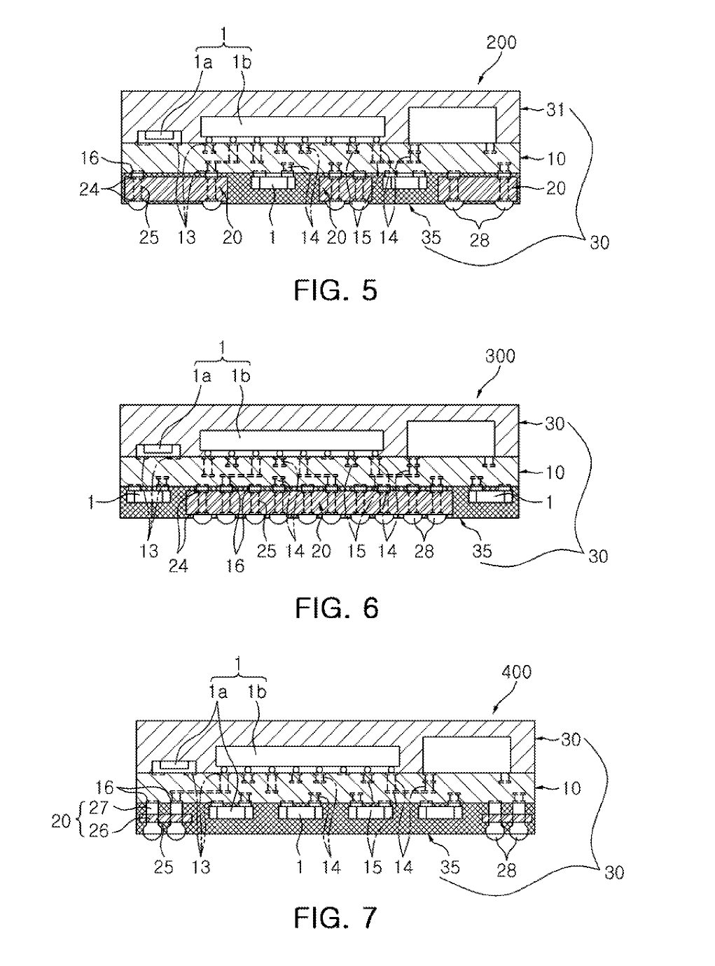

FIG. 5 is a schematic cross-sectional view of an electronic component module 200 according to another embodiment of the present disclosure.

Referring to FIG. 5, in the electronic component module 200 according to the exemplary embodiment, the second substrate 20 may be configured of a plurality of substrates, rather than a single substrate. The plurality of respective substrates may be spaced apart from each other and may be dispersedly disposed. In addition, the plurality of substrates may be consecutively arranged.

Here, the plurality of substrates of the second substrate 20 may be disposed in gaps between the electronic components 1 mounted on the lower surface of the first substrate 10 or spaces around the electronic components 1.

In addition, the plurality of substrates of the second substrate 20 may be molded to have the same shape as each other in order to facilitate the manufacturing thereof, but may be formed to different shapes as necessary.

When the plurality of substrates of the second substrate 20 are dispersedly disposed, the electronic components 1 may be mounted in various manners and the external connection terminals 28 may be effectively disposed.

FIG. 6 is a schematic cross-sectional view of an electronic component module 300 according to another embodiment of the present disclosure.

Referring to FIG. 6, in the electronic component module 300 according to the exemplary embodiment, the second substrate 20 has a smaller area than that of the first substrate 10 and is disposed on a central portion of the first substrate 10. In addition, electronic components are dispersedly disposed and mounted outside of the second substrate 20.

In a case in which the electronic component module 300 is configured as described above, the number of the external connection terminals 28 may be significantly reduced and the number of the electronic components 1 mounted on the lower portion of the first substrate 10 may be significantly reduced.

FIG. 7 is a schematic cross-sectional view of the electronic component module 400 according to another embodiment of the present disclosure.

Referring to FIG. 7, the electronic component module 400 according to the exemplary embodiment is configured in such a manner that the second substrate 20 may include a substrate frame 26 and metallic pins 27.

Here, the substrate frame 26 may be formed to have a quadrangular shape similar to the second substrate 20 shown in FIG. 3 and may have a smaller thickness than the second substrate 20.

A plurality of through holes may be formed in the substrate frame 26, and the metallic pins 27 are inserted through the through holes.

The metallic pins 27 may be formed to have a length corresponding to the thickness of the second molded part 35. The metallic pins 27 are inserted into and coupled to the substrate frame 26, such that one ends of the metallic pins 27 may be bonded to the external connection pads 16 of the first substrate 10. In addition, the other ends of the metallic pins 27 are exposed to the outside of the second molded part 35, and the external connection terminals 28 are formed on the exposed ends.

The second substrate 20 configured as described above according to the exemplary embodiment may be manufactured by preparing the substrate frame 26 in which through holes are formed and coupling the metallic pins 27 into the through holes of the substrate frame 26. Thus, the electronic component module 400 may be very easily manufactured.

When only the metallic pins 27 are mounted on the first substrate 10 without the substrate frame 26 and then the second molded part 35 is formed, the metallic pins 27 may be easily separated from the first substrate 10 due to the liquidity of molding rein. That is, the metallic pins 27 alone are bonded to the first substrate 10 and thus may be easily separated by external force.

However, the second substrate 20 according to the exemplary embodiment is formed in such a manner that a plurality of metallic pins 27 are integrally formed using the substrate frame 26. Accordingly, during a manufacturing process, the plurality of metallic pins 27 may be simultaneously mounted on the first substrate 10, and thus, the electronic component module 400 may be easily manufactured.

Since the plurality of metallic pins 27 are bonded to the first substrate 10 to increase adhesion between the plurality of metallic pins 27 and the first substrate 10, the second substrate 20 may be stably bonded to the first substrate 10. Thus, while the second molded part 35 is formed, the second molded part 35 may not be easily separated from the first substrate 10 due to the liquidity of molding rein.

The electronic component module 400 according to the exemplary embodiment may be manufactured by the same method as that of the foregoing embodiment. However, embodiments of the present disclosure are not limited thereto. A method for forming the external connection terminals 28 may be modified.

For example, in the electronic component module 400 according to the exemplary embodiment, the second molded part 35 is formed, an external surface of the second molded part 35, that is, a bottom surface of the electronic component module 100, that is, a lower surface of the second molded part 35 may be ground to completely expose the other ends of the metallic pins 27 outwardly, and then, the external connection terminals 28 are formed on the metallic pins 27. In this case, compared with the foregoing embodiment, the thickness of the electronic component module 100 may be reduced.

In the exemplary embodiment, the second substrate may be formed as an integrated substrate having a quadrangular type. However, embodiments of the present disclosure are not limited thereto. That is, the second substrate 20 may be modified in various manners similar to the second substrate described with reference to FIG. 5 or 6.

As set forth above, in the electronic component module according to the embodiments of the present disclosure, electronic components are mounted on both surfaces of the first substrate. In addition, external connection terminals may be formed on the second substrate disposed on the lower surface of the first substrate.

Thus, a plurality of electronic components may be mounted on a single substrate (that is, the first substrate), thereby increasing integration density. In addition, the external connection terminals for the first substrate on which the electronic components are mounted may be formed using the second substrate provided as a separate substrate, and thus, the formation of external connection terminals may be facilitated.

In the electronic component module according to the embodiments of the present disclosure, even in a case in which electronic components are mounted on both surfaces of the first substrate, the electronic components may be encapsulated by the first and second molded parts. Thus, even in a case in which the second substrate or the electronic components are separated from the first substrate due to heat generated at the time of mounting the electronic component module on another main substrate, movements of the electronic component module may be fixed by the molded parts.

Accordingly, bonding reliability between electronic components and a substrate may be enhanced.

While exemplary embodiments have been shown and described above, it will be apparent to those skilled in the art that modifications and variations could be made without departing from the spirit and scope of the present disclosure as defined by the appended claims.

What is claimed is:

1. An electronic component module comprising:
a first substrate;
a plurality of electronic components mounted on both surfaces of the first substrate;
a second substrate bonded to a lower surface of the first substrate; and
a molded part formed on the lower surface of the first substrate and having the second substrate embedded therein.

2. The electronic component module of claim 1, further comprising: a plurality of external connection terminals bonded to a lower surface of the second substrate and penetrating through the molded part to be exposed to the outside of the molded part.

3. The electronic component module of claim 1, wherein the molded part fills a gap formed between the lower surface of the first substrate and an upper surface of the second substrate.

4. The electronic component module of claim 1, wherein the molded part is formed on the lower surface of the first substrate, while embedding the electronic components mounted on a lower portion of the first substrate and the entirety of the second substrate therein.

5. The electronic component module of claim 1, wherein the second substrate includes a through portion formed therein and is bonded to the lower surface of the first substrate to accommodate the electronic components mounted on the lower surface of the first substrate in the through portion.

6. The electronic component module of claim 1, wherein the second substrate includes a plurality of substrates spaced apart from each other and dispersedly disposed.

7. The electronic component module of claim 1, wherein
the second substrate is formed to be smaller than the first substrate and is disposed on a central portion of the first substrate; and
the electronic components are disposed outside of the second substrate.

8. The electronic component module of claim 1, wherein the second substrate includes:
a substrate frame; and
a plurality of metallic pins penetrating through and coupled to the substrate frame and having one ends bonded to the first substrate.

9. The electronic component module of claim 8, wherein the other ends of the metallic pins are exposed to the outside of the molded part.

10. The electronic component module of claim 8, further comprising: a plurality of external connection terminals bonded to the other ends of the metallic pins.

11. An electronic component module comprising:
a first substrate;
a plurality of electronic components mounted on both surfaces of the first substrate;
a second substrate bonded to a lower surface of the first substrate; and
a molded part formed on the both surfaces of the first substrate to encapsulate the electronic components and the second substrate.

12. The electronic component module of claim 11, further comprising: a plurality of external connection terminals bonded to a lower surface of the second substrate and penetrating through the molded part to be exposed to the outside of the molded part.

13. A method of manufacturing an electronic component module, the method comprising:
preparing a first substrate;
mounting electronic components on an upper surface of the first substrate;
forming a first molded part on the upper surface of the first substrate;
mounting a plurality of second substrates and electronic components on a lower surface of the first substrate; and
forming a second molded part to embed the second substrates therein.

14. The method of claim 13, wherein the mounting of the plurality of second substrates includes:
applying a solder paste onto the lower surface of the first substrate;
disposing the electronic components and the plurality of second substrates on the solder paste; and
hardening the solder paste to fixedly bond the electronic components and the second substrates to the lower surface of the first substrate.

15. The method of claim 13, further comprising: forming external connection terminals on the second substrates after the forming of the second molded part.

16. The method of claim 15, wherein the forming of the external connection terminals includes:
forming terminal holes in a lower surface of the second molded part; and
forming the external connection terminals on the second substrates through the terminal holes.

17. The method of claim 16, wherein the forming of the terminal holes includes forming the through holes in positions corresponding to electrode pads formed on the second substrates.

18. The method of claim 13, wherein each of the second substrates includes a through portion formed therein and is bonded to the lower surface of the first substrate to accommodate the electronic components mounted on the lower surface of the first substrate in the through portion.

19. The method of claim 13, wherein each of the second substrates includes a plurality of substrates spaced apart from each other and dispersedly disposed.

20. The method of claim 13, wherein the second substrates are formed to be smaller than the first substrate and disposed on a central portion of the first substrate; and
the electronic components are disposed outside of the second substrates.

21. The method of claim 13, wherein the second substrates include:
a substrate frame; and
a plurality of metallic pins penetrating through and coupled to the substrate frame and having one ends bonded to the first substrate.

22. The method of claim 21, further comprising: after the forming of the second molded part,
grinding a lower surface of the second molded part to expose the other ends of the metallic pins; and
forming external connection terminals on the other ends of the metallic pins.
